(19) United States
(12) Patent Application Publication
(10) Pub. No.: US 2024/0344201 A1
(43) Pub. Date: Oct. 17, 2024

(54) SHOWERHEAD TEMPERATURE BASED DEPOSITION TIME COMPENSATION FOR THICKNESS TRENDING IN PECVD DEPOSITION SYSTEM

(71) Applicant: LAM RESEARCH CORPORATION, Fremont, CA (US)

(72) Inventors: Dong WANG, Sherwood, OR (US); Tu HONG, Tualatin, OR (US); Wenija SHEIN, Tigard, OR (US); Hu KANG, Tualatin, OR (US); Marc KOLLRACK, Portland, OR (US); Sky MULLENAUX, Tigard, OR (US)

(21) Appl. No.: 18/580,384

(22) PCT Filed: Jul. 15, 2022
(86) PCT No.: PCT/US2022/037273

§ 371 Date: Jan. 18, 2024

Related U.S. Application Data
(60) Provisional application No. 63/224,027, filed on Jul. 21, 2021.

(51) Int. Cl. C23C 16/455; C23C 16/52; H01J 37/32

(52) U.S. Cl. CPC C23C 16/45565; C23C 16/52; H01J 37/3244; H01J 37/32522; H01J 37/32935; H01J 2237/3321

(57) ABSTRACT

A controller for a processing chamber configured to perform a deposition process on a substrate comprises a temperature monitor configured to obtain a temperature of a showerhead of the processing chamber, a deposition time determiner configured to determine an optimized deposition time based on the obtained temperature of the showerhead and data that correlates the temperature of the showerhead with at least one of the optimized deposition time, a deposition thickness, and a deposition rate, and a deposition optimizer configured to perform a deposition step on the substrate based on the determined optimized deposition time.

### CROSS-REFERENCE TO RELATED APPLICATIONS

This application claims the benefit of U.S. Provisional Application No. 63/224,027, filed on Jul. 21, 2021. The entire disclosure of the application referenced above is incorporated herein by reference.

### FIELD

The present disclosure relates to adjusting deposition parameters to compensate for showerhead temperature in a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments such as deposition and etching of film on substrates such as semiconductor wafers. For example, deposition may be performed to deposit conductive film, dielectric film, or other types of film using chemical vapor deposition (CVD), plasma enhanced CVD (PECVD), atomic layer deposition (ALD), plasma enhance ALD (PEALD), and/or other deposition processes. During deposition, the substrate is arranged on a substrate support (e.g., a pedestal) and one or more precursor gases may be supplied to a processing chamber using a gas distribution device (e.g., a showerhead) during one or more process steps. In a PECVD or PEALD process, plasma is used to activate chemical reactions within the processing chamber during deposition.

### SUMMARY

A controller for a processing chamber configured to perform a deposition process on a substrate comprises a temperature monitor configured to obtain a temperature of a showerhead of the processing chamber, a deposition time determiner configured to determine an optimized deposition time based on the obtained temperature of the showerhead and data that correlates the temperature of the showerhead with at least one of the optimized deposition time, a deposition thickness, and a deposition rate, and a deposition optimizer configured to perform a deposition step on the substrate based on the determined optimized deposition time.

In other features, the temperature monitor is configured to receive a signal from a sensor indicating the temperature of the showerhead. The sensor is a temperature probe arranged within the showerhead. To determine the optimized deposition time, the deposition time determiner is configured to determine the optimized deposition time based on a baseline deposition time and the temperature of the showerhead. To determine the optimized deposition time, the deposition time determiner is configured to one of (i) decrease the optimized deposition time as the temperature of the showerhead increases and increase the optimized deposition time as the temperature of the showerhead decreases and (ii) increase the optimized deposition time as the temperature of the showerhead increases and decrease the optimized deposition time as the temperature of the showerhead decreases.

To determine the optimized deposition time, the deposition time determiner is configured to determine the optimized deposition time based on a baseline deposition time and a correction factor. The deposition time determiner is configured to determine the correction factor based on the temperature of the showerhead. The deposition time determiner is configured to determine the correction factor further based on at least one of accumulation and substrate count.

A system comprises the controller, the showerhead, and a temperature probe arranged within the showerhead. The temperature probe is configured to sense the temperature of the showerhead. The showerhead is not configured for active temperature control. The system further comprises a plurality of the showerheads and temperature probes arranged within the showerheads. The deposition optimizer is configured to independently perform deposition on substrates arranged in different processing stations based on respective determined optimized deposition times.

A method of performing a deposition process on a substrate in a processing chamber comprises obtaining a temperature of a showerhead of the processing chamber, determining an optimized deposition time based on the obtained temperature of the showerhead and data that correlates the temperature of the showerhead with at least one of the optimized deposition time, a deposition thickness, and a deposition rate, and performing a deposition step on the substrate based on the optimized deposition time.

In other features, the method further comprises receiving a signal from a sensor indicating the temperature of the showerhead. The method further comprises receiving a signal from a temperature probe arranged within the showerhead. Determining the optimized deposition time comprises determining the optimized deposition time based on a baseline deposition time and the temperature of the showerhead. Determining the optimized deposition time comprises at least one of (i) decreasing the optimized deposition time as the temperature of the showerhead increases and increasing the optimized deposition time as the temperature of the showerhead decreases and (ii) increasing the optimized deposition time as the temperature of the showerhead increases and decreasing the optimized deposition time as the temperature of the showerhead decreases.

In other features, determining the optimized deposition time comprises determining the optimized deposition time based on a baseline deposition time and a correction factor. The method further comprises determining the correction factor based on the temperature of the showerhead. The method further comprises determining the correction factor further based on at least one of accumulation and substrate count.

A system comprises a showerhead for a processing chamber configured to perform a deposition process on a substrate and a controller. The controller is configured to obtain a temperature of the showerhead, determine an optimized deposition time based on the obtained temperature of the showerhead and data that correlates the temperature of the showerhead with at least one of the optimized deposition time, a deposition thickness, and a deposition rate, and perform a deposition step on the substrate based on the optimized deposition time. The showerhead comprises a temperature probe configured to sense the temperature of the showerhead and provide a signal that indicates the temperature of the showerhead to the controller, and the showerhead is not configured for active temperature control.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIG. 2 is an example controller and showerhead according to the present disclosure;

FIG. 3 illustrates steps of an example method of determining a deposition time according to the present disclosure; and

FIG. 4 is an example computing system configured to implement a controller according to the present disclosure.

In the drawings, reference numbers may be reused to identify similar and/or identical elements.

### DETAILED DESCRIPTION

In substrate processing systems, process uniformity may vary based on a temperature of a gas distribution device (e.g., a showerhead configured to flow process gases, plasma, etc. into a processing chamber). For example, a deposition rate of a plasma-enhanced chemical vapor deposition (PECVD) process may vary as showerhead temperature varies. In one example, as showerhead temperature increases, deposition thickness also increases (which may be referred to as thickness trending).

In some systems, the temperature of the showerhead is controlled to maintain desired process uniformity. In other words, the showerhead may be configured for active temperature control. For example, a showerhead may be heated with embedded heaters and/or cooled with a gas or liquid coolant to control the temperature based on a predetermined temperature control strategy to compensate for known process variations. In some examples, showerhead temperature is passively controlled. For example, the showerhead is heated by generating plasma using RF power provided to an electrode of the showerhead. Heating or cooling of the showerhead may be performed prior to beginning and/or during a deposition process without real-time monitoring of showerhead temperature. However, adjusting showerhead temperature in this manner (e.g., prior to performing deposition on each substrate) increases process time, decreases throughput, and may not compensate for unpredictable or more complex temperature variations.

In other examples, the showerhead may be continuously heated and/or cooled to maintain a desired temperature during processing of the substrate. However, systems configured to continuously monitor and adjust showerhead temperature increase design complexity and cost.

Systems and methods according to the present disclosure are configured to adjust deposition parameters such as process time (e.g., a deposition, time, period or duration) to compensate for variations in showerhead temperature without continuously adjusting the showerhead temperature. In other words, instead of adjusting the showerhead temperature (e.g., the system is not configured to actively adjust showerhead temperature using controllable heater, such as a resistive heater), the deposition time may be increased or decreased to compensate for changes in deposition rates caused by variations in the showerhead temperature. For example, stored data may correlate showerhead temperature to deposition time, deposition thickness for a baseline deposition time, a deposition rate, etc. As used herein, the baseline deposition time corresponds to a default deposition time for a desired deposition thickness. Accordingly, as variations in showerhead temperature are monitored prior to and/or during a deposition step, the deposition time may be automatically adjusted based on the variations in showerhead temperature.

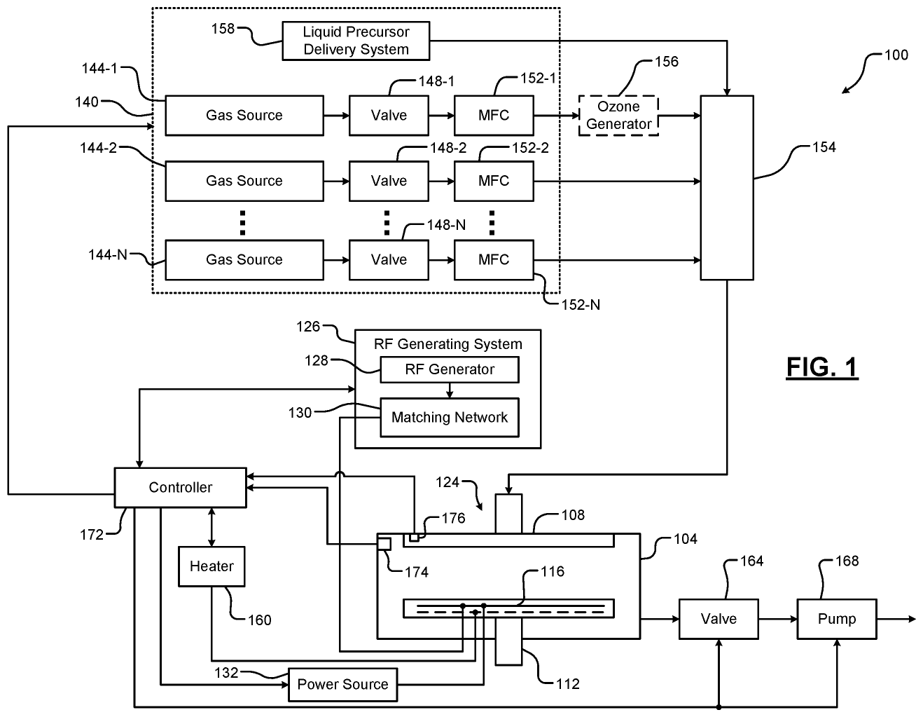

Referring now to FIG. 1, an example of a substrate processing system 100 according to the principles of the present disclosure is shown. While the foregoing example relates to PECVD systems, other plasma-based substrate processing chambers may be used. The substrate processing system 100 comprises a processing chamber 104 that encloses other components of the substrate processing system 100. The substrate processing system 100 comprises a first electrode 108 and a substrate support such as a pedestal 112 comprising a second electrode 116. For example, the first electrode 108 may be an upper electrode. The second electrode 116 may be a lower electrode. A substrate (not shown) is arranged on the pedestal 112 between the first electrode 108 and the second electrode 116 during processing.

For example only, the first electrode 108 may comprise a showerhead 124 that introduces and distributes process gases. In some examples, the showerhead 124 may not be configured for active temperature control. For example, the showerhead 124 is not configured to be actively heated and/or cooled (e.g., using resistive heaters, coolant flowed through coolant channels, etc.). In other words, the showerhead 124 does not comprise active heating components (e.g., embedded resistive heaters) and/or does not comprise active cooling components (e.g., channels configure to flow coolant throughout the showerhead 124). The second electrode 116 may correspond to a conductive electrode embedded within a non-conductive pedestal. Alternately, the pedestal 112 may comprise an electrostatic chuck that comprises a conductive plate that acts as the second electrode 116.

A radio frequency (RF) generating system 126 generates and outputs an RF voltage to the first electrode 108 and/or the second electrode 116 when plasma is used. In some examples, one of the first electrode 108 and the second electrode 116 may be DC grounded, AC grounded, or at a floating potential. For example only, the RF generating system 126 may comprise one or more RF voltage generators 128 (e.g., a capacitively-coupled plasma RF power generator, a bias RF power generator, and/or other RF power generator) such as an RF generator 128 that generate RF voltages. The RF voltages are fed by one or more matching and distribution networks 130 to the second electrode 116 and/or the first electrode 108. For example, as shown, the RF generator 128 provides an RF and/or bias voltage to the second electrode 116. The second electrode 116 may receive power alternatively or additionally from other power sources, such as a power source 132. In other examples, an RF voltage may be supplied to the first electrode 108 or the first electrode 108 may be connected to a ground reference.

An example gas delivery system 140 comprises one or more gas sources 144-1, 144-2, . . . , and 144-N (collectively gas sources 144), where N is an integer greater than zero. The gas sources 144 supply one or more gases (e.g., precursors, inert gases, etc.) and mixtures thereof. Vaporized precursor may also be used. At least one of the gas sources 144 may contain gases used in the pre-treatment process of the present disclosure (e.g., NH₃, N₂, etc.). The gas sources 144 are connected by valves 148-1, 148-2, . . . , and 148-N (collectively valves 148) and mass flow controllers 152-1, 152-2, . . . , and 152-N (collectively mass flow controllers 152) to a manifold 154. An output of the manifold 154 is fed to the processing chamber 104. For example only, the output of the manifold 154 is fed to the showerhead 124.

In some examples, an optional ozone generator 156 may be provided between the mass flow controllers 152 and the manifold 154. In some examples, the substrate processing system 100 may comprise a liquid precursor delivery system 158. The liquid precursor delivery system 158 may be incorporated within the gas delivery system 140 as shown or may be external to the gas delivery system 140. The liquid precursor delivery system 158 is configured to provide precursors that are liquid and/or solid at room temperature via a bubbler, direct liquid injection, vapor draw, etc.

A heater 160 may be connected to a heater coil 162 arranged in the pedestal 112 to heat the pedestal 112. The heater 160 may be used to control a temperature of the pedestal 112 and the substrate.

A valve 164 and pump 168 may be used to evacuate reactants from the processing chamber 104. A controller 172 may be used to control various components of the substrate processing system 100. For example only, the controller 172 may be used to control flow of process, carrier, and precursor gases, striking and extinguishing plasma, removal of reactants, monitoring of chamber parameters, etc. The controller 172 may receive measurement signals indicative of process parameters, conditions within the processing chamber 104, etc. via one or more sensors 174 arranged throughout the substrate processing system 100.

The controller 172 according to the present disclosure is further configured to monitor a temperature of the showerhead 124. The controller 172 is further configured to adjust process time (e.g., deposition time, period, or duration) to compensate for variations in the showerhead temperature. For example, one or more sensors 176 in contact with and/or embedded within the showerhead 124 are configured to monitor a temperature of the showerhead 124 during deposition. The controller 172 receives a signal from the sensor 176 indicating the showerhead temperature. The controller 172 is configured to selectively (e.g., periodically or continuously) determine and update deposition time based on the monitored temperature of the showerhead 124 as described below in more detail.

While described below with respect to a single processing chamber 104 and pedestal 112, the principles of the present disclosure may be implemented in systems comprising multiple processing chambers and processing chambers comprising multiple processing stations and pedestals, such as a quad station module (QSM). For example, each showerhead 124 in a corresponding processing station of a QSM may implement one or more sensors for monitoring temperature and adjusting deposition accordingly. In other words, deposition times at each processing station can be independently adjusted to compensate for temperatures of respective ones of the showerheads 124.

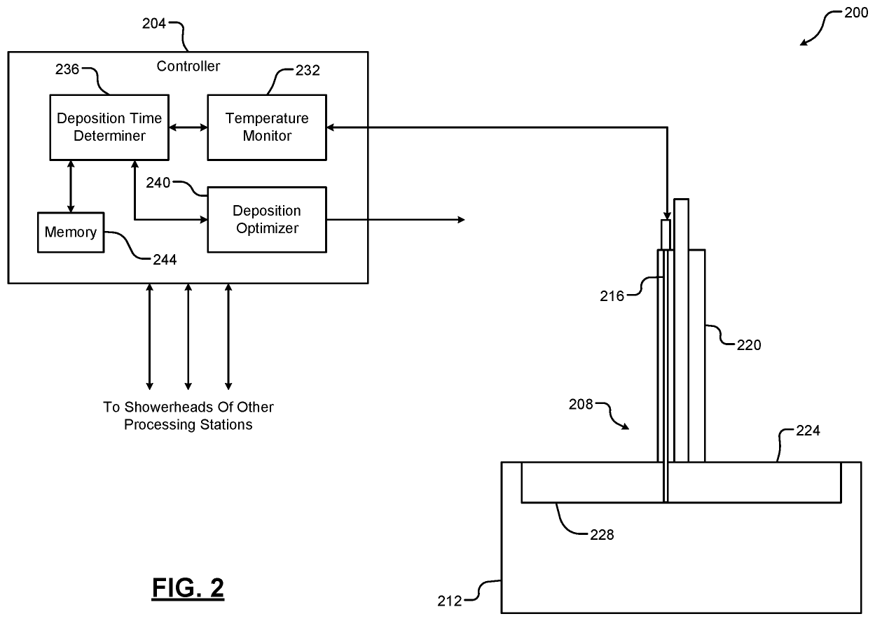

Referring now to FIG. 2, an example system 200 according to the present disclosure comprises a controller 204 (e.g., corresponding to the controller 172) configured to monitor a temperature of a showerhead 208. The showerhead 208 is not configured for active or passive temperature adjustment. For example, the showerhead 208 does not comprise a heater (e.g., a resistive heater). The controller 204 adjusts a deposition time (i.e., period or duration) to compensate for variations in the showerhead temperature. For example, the showerhead 208 is arranged to provide process gases to a processing chamber 212.

The showerhead 208 and the processing chamber 212 may correspond to a single processing station in a multi-station processing tool (e.g., a quad station module). The controller 204 may be configured to monitor temperatures of a plurality of showerheads of respective processing stations, independently adjust deposition times in each of the processing stations, etc. Alternatively, the controller 204 may adjust deposition times in a plurality of stations based on monitored temperatures of only one of the showerheads (e.g., the showerhead 208).

In this example, a temperature probe 216 is routed through a stem 220 of the showerhead and into a base 224 of the showerhead 208. For example, an end of the temperature probe 216 may be located near or in contact with a lower surface 228 of the showerhead 208. In other examples, one or more temperature sensors (e.g., thermocouples) are arranged on or embedded in the showerhead 208. For example only, when more than one temperature sensor is used (i.e., more than one sensed temperature is provided to the controller 204 from different locations), the controller 204 may adjust the deposition time based on an average of a plurality of sensed temperatures).

The controller 204 comprises a temperature monitor 232, a deposition time determiner 236, and a deposition optimizer 240. The temperature monitor 232 receives and processes one or more signals from the temperature probe 216 indicating the temperature of the showerhead 208. For example, the received signals may be analog signals. The temperature monitor 232 may be configured to convert the analog signals to digital values corresponding to temperatures. The temperature monitor 232 outputs a signal indicating the sensed showerhead temperature to the deposition time determiner 236.

The deposition time determiner 236 is configured to determine a deposition time for a deposition step based on the sensed showerhead temperature. Deposition thickness may be directly correlated (e.g., linearly correlated) to showerhead temperature. For example, as showerhead temperature increases, deposition thickness for a fixed deposition duration may also increase. Conversely, as showerhead temperature decreases, deposition thickness for the same fixed deposition duration also decreases. In some examples, deposition thickness may decrease as showerhead temperature increases and increase as showerhead temperature decreases. The deposition time determiner 236 determines and selectively adjusts the deposition time to compensate for variations in showerhead temperature and achieve a desired deposition thickness.

In one example, the deposition time determiner 236 receives the showerhead temperature and determines the deposition time prior to beginning a deposition step or process. For example, the deposition time determiner 236 determines the deposition time for a next substrate subsequent to performing deposition on a previous substrate (i.e., between deposition steps performed on successive substrates in a sequence). The deposition time determiner 236 determines the deposition time based on the showerhead temperature and a desired deposition thickness. Alternatively, the deposition time determiner 236 determines an adjustment or offset to a baseline or default deposition time (e.g., a deposition time adjustment percentage, time offset, etc.). The deposition time determiner 236 provides deposition time information (e.g., the determined deposition time, a deposition time adjustment, etc.) to the deposition optimizer 240. The deposition optimizer 240 controls the deposition step for a deposition duration based on the deposition information.

In another example, the deposition time determiner 236 continues to determine the deposition time based on showerhead temperatures sensed and received during the deposition step. In other words, instead of determining the deposition time only once prior to beginning the deposition step and performing the deposition step for the determined deposition time, the deposition time determiner 236 may make further adjustments to the deposition time based on temperature variation during the deposition step (i.e., in real-time as a deposition step is being performed).

The deposition time determiner 236 determines the deposition time based on data that correlates showerhead temperature to a deposition rate, a deposition thickness for a baseline deposition time, etc. For example, the data corresponds to showerhead temperature compensation data stored in memory 244. In one example, the stored data may comprise a lookup table that correlates showerhead temperature to deposition rate, deposition thickness, a deposition time for a desired deposition thickness, etc. In another example, the stored data is a model or formula configured to determine a deposition time based on one or more inputs comprising, but not limited to, the showerhead temperature as measured prior to the deposition step and a default or baseline deposition time.

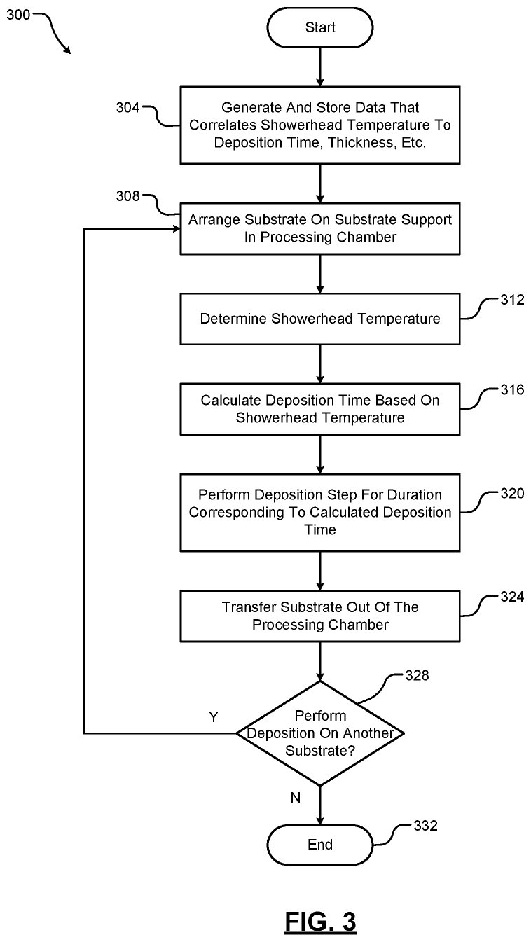

Referring now to FIG. 3, an example method 300 of determining a deposition time according to the present disclosure is shown. For example, the system 200 of FIG. 2 is configured to perform the method 300. At 304, showerhead temperature compensation data is generated and stored. For example, showerhead temperature compensation data is data correlating showerhead temperature to deposition rate, a deposition thickness for a baseline deposition time, etc. as described above. In one example, multiple substrates are processed (e.g., in sequential deposition steps having a same deposition time) while showerhead temperature is monitored. After deposition is complete, respective deposition thicknesses of the substrates are measured. In this manner, respective showerhead temperatures for each deposition thickness (at the same deposition time) can be determined.

At 308, a substrate is arranged on a substrate support in a processing chamber configured to perform a deposition process on the substrate. At 312, the method 300 (e.g., the temperature monitor 232) determines a temperature of a showerhead of the processing chamber. For example, the temperature monitor 232 receives one or more signals from respective sensors (e.g., the temperature probe 216) configured to sense a temperature of the showerhead.

At 316, the method 300 (e.g., the deposition time determiner 236) determines a deposition time based on the showerhead temperature. For example, the deposition time determiner 236 determines the deposition time based on the stored data that correlates showerhead temperature to deposition time and/or thickness as described above. In one example, the stored data is a model or formula configured to determine an adjusted (i.e., optimized) deposition time DT′ based on a baseline deposition time DT and a variable correction factor C according to DT′=DT*C. In some examples, the correction factor is inversely proportional to showerhead temperature. Accordingly, as showerhead temperature increases, the correction factor C decreases (e.g., from a baseline of 1) and the optimized deposition time DT′ decreases. In other examples, the correction factor is directly proportional to showerhead temperature. Accordingly, as showerhead temperature increases, the correction factor C increases and the optimized deposition time DT′ increases.

The correction factor C may be determined based only on the showerhead temperature or based on the showerhead temperature and other inputs such accumulation (i.e., a measured or estimated amount of accumulation of deposition byproducts within the processing chamber), substrate count (i.e., a number of substrates processed in a given sequence or time period affecting showerhead temperature), etc.

At 320, the method 300 (e.g., the deposition optimizer 240 performs a deposition step for a duration corresponding to the determined optimized deposition time. For example, the deposition step is performed without pre-heating the showerhead. At 324, the substrate transferred out of the processing chamber. At 328, the method 300 determines whether to perform deposition on another substrate. If true, the method 300 continues to 308. If false, the method 300 ends at 332.

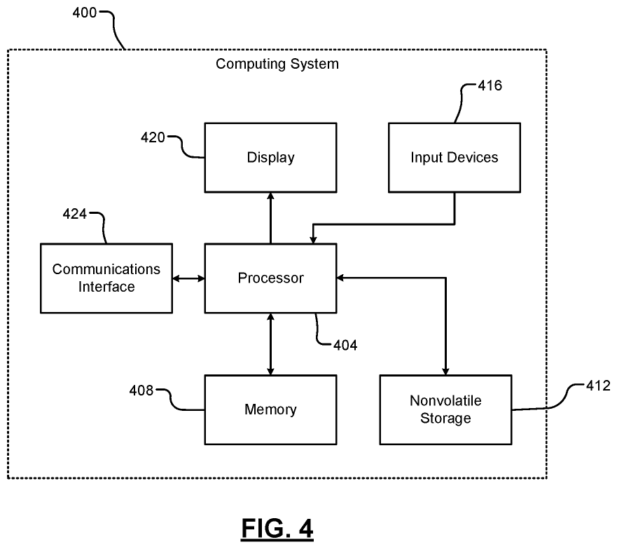

FIG. 4 shows an example computing system 400 comprising a processor 404 and memory 408 configured to implement the controller 204 of FIG. 2. For example, the computing system 400 is configured to perform the method 300 of FIG. 3. In one example, the processor 404 is a special purpose processor configured to execute instructions stored in the memory 408 and/or nonvolatile storage 412. The memory 408 may be volatile memory and/or nonvolatile memory. The nonvolatile storage 412 may comprise one or more hard disk drives, semiconductor storage (e.g., solid state drives), etc.

The computing system 424 may comprise input devices such as a keyboard or keypad, touchscreen, etc. for receiving commands and other input from a user. A display 420 is configured to display information (e.g., process parameters, images, etc.). A communications interface 424 may provide wired and/or wireless communication between the computing system 400 and devices external to the computing system, such as sensors, controllers, other processing tools, etc.

Although described above as adjusting deposition time based on the showerhead temperature, in some examples other processing parameters may be adjusted based on the showerhead temperature instead of or in addition to adjusting the deposition time. For example, systems and methods according to the present disclosure may be configured to adjust process gas flow rates, chamber pressure, RF power, etc. based on the determined showerhead temperature.

The foregoing description is merely illustrative in nature and is in no way intended to limit the disclosure, its application, or uses. The broad teachings of the disclosure can be implemented in a variety of forms. Therefore, while this disclosure comprises particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, such as “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the terms “controller,” monitor,” “determiner,” and “optimizer” may be defined as electronics having various integrated circuits, logic, memory, and/or software that receive instructions, issue instructions, control operation, enable cleaning operations, enable endpoint measurements, and the like. The integrated circuits may comprise chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may comprise a local network or the Internet. The remote computer may comprise a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may comprise a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A controller for a processing chamber configured to perform a deposition process on a substrate, the controller comprising:
a temperature monitor configured to obtain a temperature of a showerhead of the processing chamber;
a deposition time determiner configured to determine an optimized deposition time based on the obtained temperature of the showerhead and data that correlates the temperature of the showerhead with at least one of the optimized deposition time, a deposition thickness, and a deposition rate; and
a deposition optimizer configured to perform a deposition step on the substrate based on the determined optimized deposition time.

2. The controller of claim 1, wherein the temperature monitor is configured to receive a signal from a sensor indicating the temperature of the showerhead.

3. The controller of claim 2, wherein the sensor is a temperature probe arranged within the showerhead.

4. The controller of claim 1, wherein, to determine the optimized deposition time, the deposition time determiner is configured to determine the optimized deposition time based on a baseline deposition time and the temperature of the showerhead.

5. The controller of claim 4, wherein, to determine the optimized deposition time, the deposition time determiner is configured to one of (i) decrease the optimized deposition time as the temperature of the showerhead increases and increase the optimized deposition time as the temperature of the showerhead decreases and (ii) increase the optimized deposition time as the temperature of the showerhead increases and decrease the optimized deposition time as the temperature of the showerhead decreases.

6. The controller of claim 1, wherein, to determine the optimized deposition time, the deposition time determiner is configured to determine the optimized deposition time based on a baseline deposition time and a correction factor.

7. The controller of claim 6, wherein the deposition time determiner is configured to determine the correction factor based on the temperature of the showerhead.

8. The controller of claim 7, wherein the deposition time determiner is configured to determine the correction factor further based on at least one of accumulation and substrate count.

9. A system comprising the controller of claim 1 and further comprising:
the showerhead; and
a temperature probe arranged within the showerhead, wherein the temperature probe is configured to sense the temperature of the showerhead.

10. The system of claim 9, wherein the showerhead is not configured for active temperature control.

11. The system of claim 9, further comprising a plurality of the showerheads and temperature probes arranged within the showerheads, wherein the deposition optimizer is configured to independently perform deposition on substrates arranged in different processing stations based on respective determined optimized deposition times.

12. A method of performing a deposition process on a substrate in a processing chamber, the method comprising:
obtaining a temperature of a showerhead of the processing chamber;
determining an optimized deposition time based on the obtained temperature of the showerhead and data that correlates the temperature of the showerhead with at least one of the optimized deposition time, a deposition thickness, and a deposition rate; and
performing a deposition step on the substrate based on the optimized deposition time.

13. The method of claim 12, further comprising receiving a signal from a sensor indicating the temperature of the showerhead.

14. The method of claim 12, further comprising receiving a signal from a temperature probe arranged within the showerhead.

15. The method of claim 12, wherein determining the optimized deposition time comprises determining the optimized deposition time based on a baseline deposition time and the temperature of the showerhead.

16. The method of claim 15, wherein determining the optimized deposition time comprises at least one of (i) decreasing the optimized deposition time as the temperature of the showerhead increases and increasing the optimized deposition time as the temperature of the showerhead decreases and (ii) increasing the optimized deposition time as the temperature of the showerhead increases and decreasing the optimized deposition time as the temperature of the showerhead decreases.

17. The method of claim 12, wherein determining the optimized deposition time comprises determining the optimized deposition time based on a baseline deposition time and a correction factor.

18. The method of claim 17, further comprising determining the correction factor based on the temperature of the showerhead.

19. The method of claim 18, further comprising determining the correction factor further based on at least one of accumulation and substrate count.

20. A system, comprising:
a showerhead for a processing chamber configured to perform a deposition process on a substrate; and
a controller configured to
obtain a temperature of the showerhead,
determine an optimized deposition time based on the obtained temperature of the showerhead and data that correlates the temperature of the showerhead with at least one of the optimized deposition time, a deposition thickness, and a deposition rate, and
perform a deposition step on the substrate based on the optimized deposition time.
